(19) United States
(12) Patent Application Publication
(10) Pub. No.: US 2025/0044320 A1
(43) Pub. Date: Feb. 6, 2025

(54) DETACHABLE PROTECTIVE STRUCTURE OF DETECTION DEVICE

(71) Applicants: NATIONAL APPLIED RESEARCH LABORATORIES, TAIPEI CITY (TW); NATIONAL CHUNG SHAN INSTITUTE OF SCIENCE AND TECHNOLOGY, TAOYUAN CITY (TW)

(72) Inventors: GUO-WEI HUANG, HSINCHU (TW); YU-SHAO SHIAO, HSINCHU (TW)

(21) Appl. No.: 18/362,065

(22) Filed: Jul. 31, 2023

(51) Int. Cl. G01R 1/04; G01R 1/067

(52) U.S. Cl. CPC G01R 1/04; G01R 1/06705

(57) ABSTRACT

The present invention provides a detachable protective structure of detection device, which is used for accommodating a detection device. One terminal of a conducting member in the detection device is connected electrically to a signal processing module while the other terminal thereof is connected electrically to a probe. The detachable protective structure of detection device comprises a shielding member, which covers the probe of the detection device correspondingly as well as covering the signal processing module and the conducting member of the detection device. The present invention further provides different fixing embodiments for fixing the shielding member to the signal processing module, a base, a platform for moving the detection device, and the probe. The detachable protective structure of detection device can be disassembled along with the detection device from the detection platform.

### FIELD OF THE INVENTION

The present invention relates to a detachable protective structure of detection device, and particularly to an accommodating structure used for protecting detection devices from bumps and damage by accidental collisions, and also portable with detection devices.

### BACKGROUND OF THE INVENTION

In recent years, due to the rising of wireless mobile communication, the testing for microwave integrated circuits, modules, devices, and radio-frequency (RF) probing technologies becomes increasingly important, attracting probe manufacturers to work in the associated field.

RF probing plays a significant role in almost every stage in the life cycle of RF integrated circuit products, including technology development, model parameter extraction, design verification and tuning, small-scale production, and mass production. By using RF probes, designers can measure the characteristics of electronic devices at the wafer level, which can shorten research and development time as well as massively reduce the cost of developing new products.

The RF probing technology has made astonishing progress in a brief time ranging from low-frequency measurement to high-frequency commercial products for various applications such as measurement apparatuses for impedance matching, multi-port, difference, and mixed-signal measurement in 100 GHz and high-temperature environments, high-power measurement in continuous-wave mode up to 60 W, and 750 GHz applications.

The planar transmission lines of a probe should touch or contact those contact points on semiconductor chips directly but not wires on chips. For example, in microstrip and the latest coplanar probe designs, probe tips usually contact the object under test through metal spheres with a small diameter. The material strength of the metal spheres should be guaranteed for ensuring multiple measurements.

To contact the signal contact point and the ground contact point simultaneously, the probe should be tilted. This process is known as probe leveling.

The contact repeatability of probes should be much more reliable than the contact repeatability of coaxial connectors so that the development of probe tips and probe plates can be standardized and the calibration method can be developed.

Because the application frequency of RF probe technology can reach several tens of gigahertz, many phenomena will be observed, such as the skin effect, dielectric attenuation, reflection, and transmission. At such high frequencies, it is not possible to use voltage meters, current meters, and oscilloscopes. In addition, the resolution of instruments, the sensitivity, noise floor, and bandwidth of receivers, the speed of processors, and the accuracy of numerical calculations are also limited. Thereby, instead of measuring the waveform, phase, current, and voltage of microwave signals, it is the spectrum and power of microwaves that are usually measured. Microwave measurements such as reflection coefficient, return loss, standing-wave ratio, and S parameters, are hardly required in tests for digital and analog circuits.

To measure digital or analog circuits, the required instruments usually include waveform generators, oscilloscopes, voltage sources, current sources, voltage meters, current meters, logic analyzers, and curve tracers. The measured signal features include waveforms, voltages, current, and periods. Contrarily, RF devices probing have two more distinct features as described below.

First, the instruments, signal sources, and accessories used in microwave measurement are different from the required instruments in measurement for digital and analog circuits. Secondly, before microwave measurement, the components, cables, and waveguides must be calibrated for error or loss and all instruments must be zeroed. This is not common in measurement for normal electronic signals.

An RF probing device according to the prior art includes a network analyzer, a signal processing module, and a probe. The signal processing module is used for increasing the measurement frequency of the network analyzer. The probe is responsible for connecting the signal processing module with the chip. When the measurement frequency is above 75 GHz, especially a waveguide probe fixed to and moved together with the signal processing module is usually adopted.

When the measurement is finished, to avoid damaging the probe, the waveguide probe must be disassembled and secured back to the probe box. Besides, the signal processing module should be stored in a corresponding container. The disassembling and securing process is quite cumbersome and time-consuming. In addition, the process also induces concerns of damage due to the increased possibility of bumps between the signal processing module and the probe and contact with the human body. Thereby, it is highly required to have a protective structure that can support and protect RF probing devices as well as disassemble together with them.

To solve the above problems according to the prior art, the present invention provides a detachable protective structure of detection device used for accommodating detection devices. The shielding member covers the signal processing module and the probe correspondingly and further covers the conducting member of the detection device. In addition, the present invention further provides different fixing embodiments for fixing the shielding member to the signal processing module, the base, the platform for supporting, and the probe. The detachable protective structure of detection device can be disassembled along with the detection device from the detection platform.

### SUMMARY

An objective of the present invention is to provide a detachable protective structure of detection device. The shielding member covers the signal processing module and the probe correspondingly. In addition, the present invention further provides different fixing embodiments for fixing the shielding member to the signal processing module, the base, the platform for supporting, and the probe. The detachable protective structure of detection device can be disassembled along with the detection device from the detection platform.

To achieve the above objective and efficacy, the present invention provides a detachable protective structure of detection device for accommodating a detection device. The detection device includes a signal processing module, a conducting member, and a probe. The conducting member is disposed on one side of the signal processing module with one terminal connected electrically to the signal processing module. The other terminal of the conducting member is connected electrically to one side of the probe. The detachable protective structure of detection device comprises a shielding member. The shielding member includes a shielding body, a side opening, and a fixing part. The side opening passes through one side of the shielding body, covers the signal processing module correspondingly, and envelops the conducting member and the probe. The fixing part is disposed at the shielding body corresponding to an alignment part of the signal processing module. With the detection device protected, the detachable protective structure of detection device can be disassembled from or assembled to the detection platform along with the detection device.

To achieve the above objective and efficacy, the present invention provides a detachable protective structure of detection device for accommodating a detection device. The detection device includes a signal processing module, a conducting member, and a probe. The conducting member is disposed on one side of the signal processing module with one terminal connected electrically to the signal processing module. The other terminal of the conducting member is connected electrically to one side of the probe. The detachable protective structure of detection device comprises a base and a shielding member. The base is disposed below the signal processing module. An alignment part is disposed on one side of the base. The shielding member includes a shielding body, a side opening, and a fixing part. The side opening passes through one side of the shielding body, covers the signal processing module correspondingly, and envelops the conducting member and the probe. The fixing part is disposed at the shielding body corresponding to the alignment part of the signal processing module. With the detection device protected, the detachable protective structure of detection device can be disassembled from or assembled to the detection platform along with the detection device.

To achieve the above objective and efficacy, the present invention provides a detachable protective structure of detection device for accommodating a detection device. The detection device includes a signal processing module, a conducting member, and a probe. The conducting member is disposed on one side of the signal processing module with one terminal connected electrically to the signal processing module. The other terminal of the conducting member is connected electrically to one side of the probe. The detachable protective structure of detection device comprises a base, a platform, and a shielding member. The base is disposed below the signal processing module. The platform is disposed below the base and includes an alignment part. The shielding member includes a shielding body, a side opening, and a fixing part. The side opening passes through one side of the shielding body, covers the signal processing module correspondingly, and envelops the conducting member and the probe. The fixing part is disposed below the shielding body corresponding to the alignment part. With the detection device protected, the detachable protective structure of detection device can be disassembled from or assembled to the detection platform along with the detection device.

To achieve the above objective and efficacy, the present invention provides a detachable protective structure of detection device for accommodating a detection device. The detection device includes a signal processing module, a conducting member, and a probe. The conducting member is disposed on one side of the signal processing module with one terminal connected electrically to the signal processing module. The other terminal of the conducting member is connected electrically to one side of the probe. The detachable protective structure of detection device comprises a shielding member. The shielding member includes a shielding body, a side opening, a top opening, and a fixing part. The side opening passes through one side of the shielding body, and covers and envelops the probe. The top opening is connected with the side opening. The conducting member passes through the top opening. The fixing part is disposed at the shielding body corresponding to an alignment part on the probe. With the detection device protected, the detachable protective structure of detection device can be disassembled from or assembled to the detection platform along with the detection device.

According to an embodiment of the present invention, the detachable protective structure of detection device further comprises a fixing member passing through the fixing part and the alignment part correspondingly.

According to an embodiment of the present invention, the fixing part and the alignment part are screw holes, respectively, and the fixing member is a threaded member.

According to an embodiment of the present invention, the detachable protective structure of detection device further comprises a base disposed below the signal processing module.

### BRIEF DESCRIPTION OF THE DRAWINGS

FIG. 1 shows an exploded view of the structure according to the first embodiment of the present invention;

FIG. 2A shows a schematic diagram of the structure according to the first embodiment of the present invention;

FIG. 2B shows a cross-sectional view of the structure according to the first embodiment of the present invention;

FIG. 3 shows an exploded view of the structure according to the second embodiment of the present invention;

FIG. 4A shows a schematic diagram of the structure according to the second embodiment of the present invention;

FIG. 4B shows a cross-sectional view of the structure according to the second embodiment of the present invention;

FIG. 5 shows an exploded view of the structure according to the third embodiment of the present invention;

FIG. 6 shows a schematic diagram of the structure according to the third embodiment of the present invention;

FIG. 7 shows an exploded view of the structure according to the fourth embodiment of the present invention; and

FIG. 8 shows a schematic diagram of the structure according to the fourth embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The present invention provides a detachable protective structure of detection device, which is used for accommodating a detection device. A shielding member covers a signal processing module, a probe, and a conducting member of the detection device correspondingly. According to different embodiments, the shielding member is fixed at the signal processing module, a base, a platform for supporting, and a probe. With the RF probing device supported and protected, the detachable protective structure of detection device can be disassembled along with the detection device.

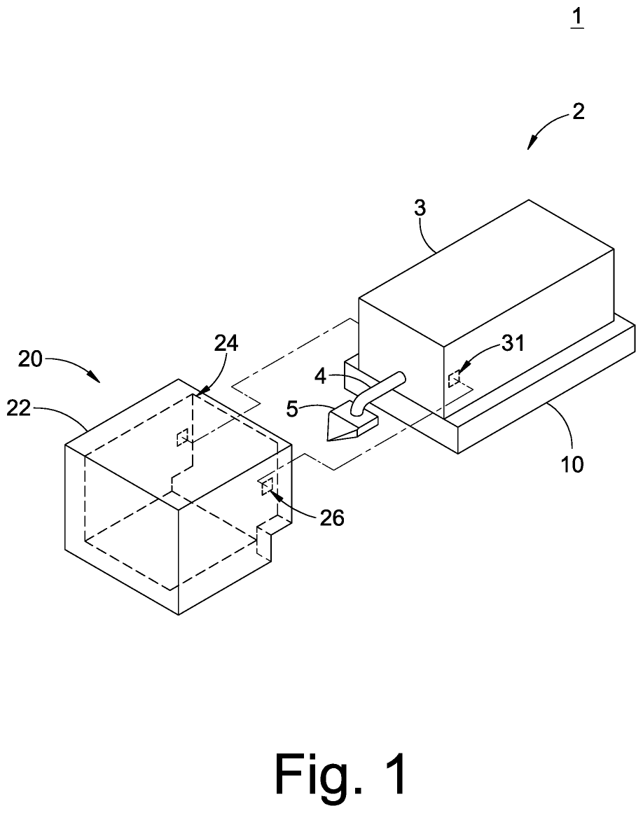

Please refer to FIG. 1, which shows an exploded view of the structure according to the first embodiment of the present invention. As shown in the figure, the first embodiment of the present invention discloses a detachable protective structure of detection device 1, which is used for accommodating a detection device 2. The detection device 2 includes a signal processing module 3, a conducting member 4, and a probe 5. One terminal of the conducting member 4 is connected electrically to the signal processing module 3. The other terminal of the conducting member 4 is connected electrically to the probe 5. The detachable protective structure of detection device 1 comprises a shielding member 20. According to the present embodiment, the probe 5 is a waveguide probe. According to the present embodiment, the signal processing module 3 is a frequency extension module or a load adjustment module of the waveguide probe. The present invention is not limited to the present embodiment.

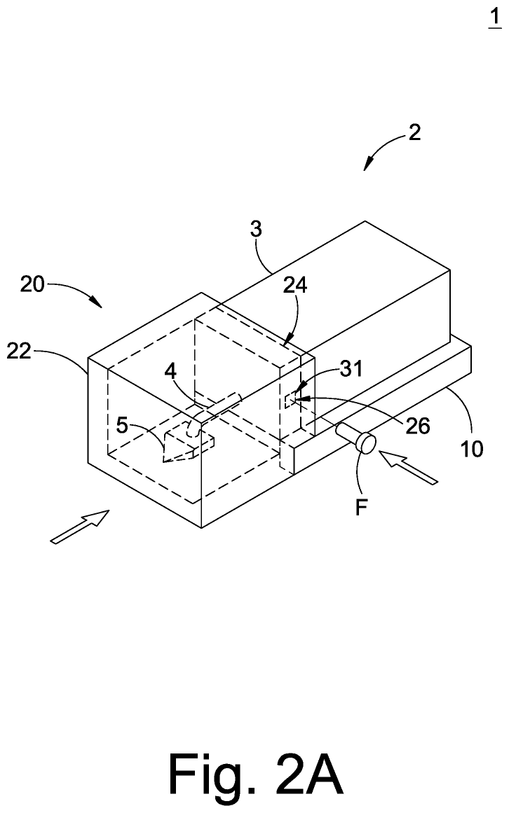

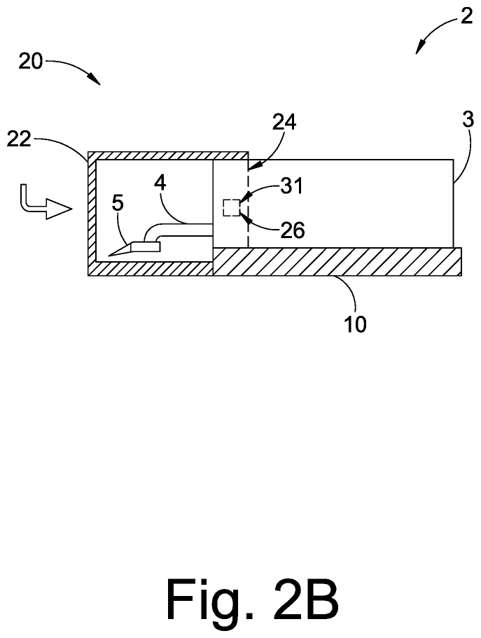

Please refer to FIG. 1 again and to FIG. 2A and FIG. 2B. FIG. 2A shows a schematic diagram of the structure according to the first embodiment of the present invention; FIG. 2B shows a cross-sectional view of the structure according to the first embodiment of the present invention. As shown in the figures, according to the present embodiment, the shielding member 20 includes a shielding body 22, a side opening 24, and a fixing part 26. The side opening 24 passes through one side of the shielding body 22, covers the signal processing module 3 correspondingly, and envelops the conducting member 4 and the probe 5. The fixing part 26 is disposed at the shielding body 22 corresponding to an alignment part 31 of the signal processing module 3. The shielding member 20 is used for protecting the components and preventing damage and external pollutants from contacting the conducting member 4 and the probe 5.

According to the present embodiment, the signal processing module 3 of the detection device 2 extends downwards and is connected electrically to the terminal of the conducting member 4. The other terminal of the conducting member 4 extends downwards and is connected electrically to the side of the probe 5. The alignment part 31 is disposed at the housing of the signal processing module 3 corresponding to the fixing part 26 of the shielding body 22 for fixing the shielding member 20 on the outer side of the signal processing module 3. Thereby, according to the present embodiment, the size (for example, the width of the opening) of the side opening 24 of the shielding body 22 must be greater than the size of the signal processing module 3 for covering the signal processing module 3 and preventing the signal processing module 3 from damage. In this embodiment, the alignment part 31 and the fixing part 26 can be glue, tenon, touch fasteners, snap-fit method, clip-on method, hook-and-loop fastener method, and other removable fixing methods (for example, the fixing part 26 is provided with a ring-shaped structure of touch fasteners, and the alignment part 31 is provided with a hook-shaped structure of touch fasteners, and the two are correspondingly fixed).

Please refer to FIG. 1 to FIG. 2B again. As shown in the figures, according to the present embodiment, the detachable protective structure of detection device 1 further comprises a fixing member F. The fixing member F passes through the fixing part 26 at the shielding body 22 and the alignment part 31 at the signal processing module 3 for fixing the shielding member 20 to the outer side of the signal processing module 3. According to the present embodiment, the fixing part 26 and the alignment part 31 are screw holes, respectively. The fixing member F is a threaded member. The threaded member is screwed into the screw holes for fixing. Nonetheless, the present invention is not limited to the embodiment.

According to the present embodiment, the detachable protective structure of detection device 1 further comprises a base 10 disposed below the signal processing module 3. The base 10 is used for supporting the signal processing module 3 and further disposing the signal processing module 3 on the movable platform.

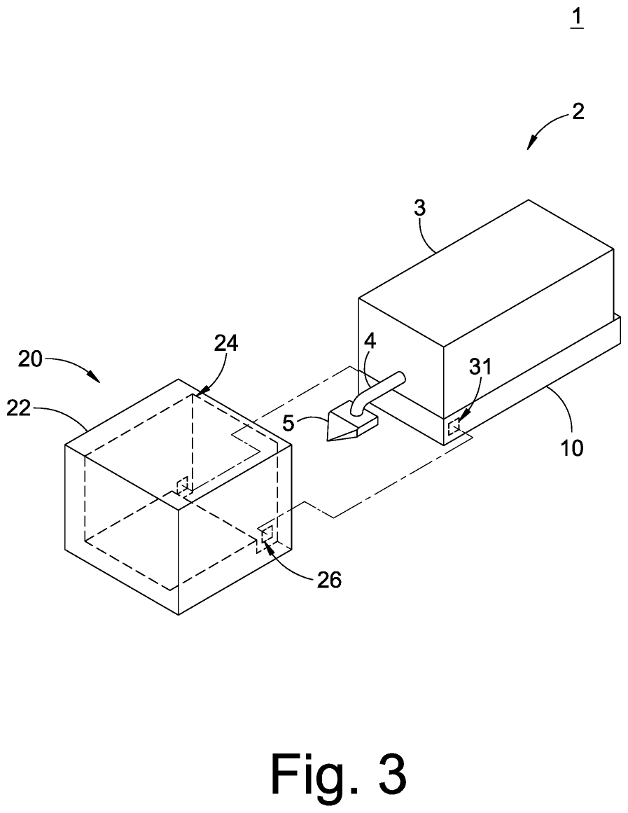

Please refer to FIG. 3, which shows an exploded view of the structure according to the second embodiment of the present invention. As shown in the figure, the second embodiment of the present invention discloses a detachable protective structure of detection device 1, which is used for accommodating a detection device 2. The detection device 2 includes a signal processing module 3, a conducting member 4, and a probe 5. One terminal of the conducting member 4 is connected electrically to the signal processing module 3. The other terminal of the conducting member 4 is connected electrically to the probe 5. The detachable protective structure of detection device 1 comprises a base 10 and a shielding member 20. According to the present embodiment, the probe 5 is a waveguide probe. According to the present embodiment, the signal processing module 3 is a frequency extension module or a load adjustment module of the waveguide probe. The present invention is not limited to the present embodiment.

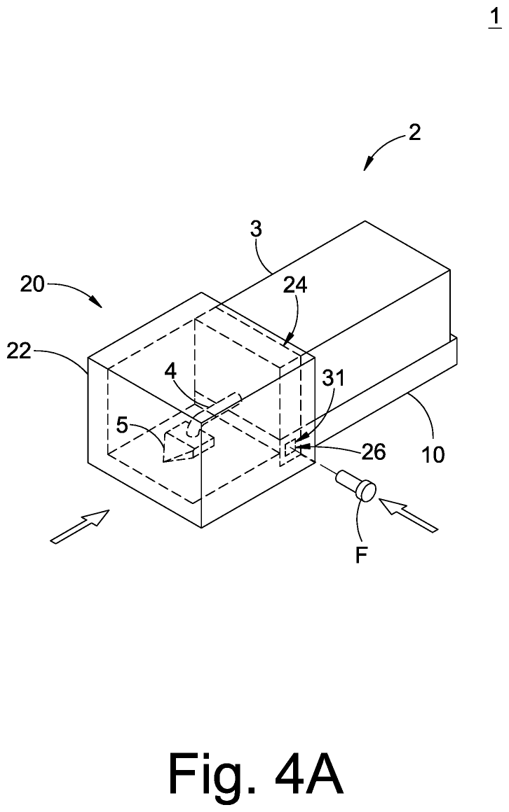

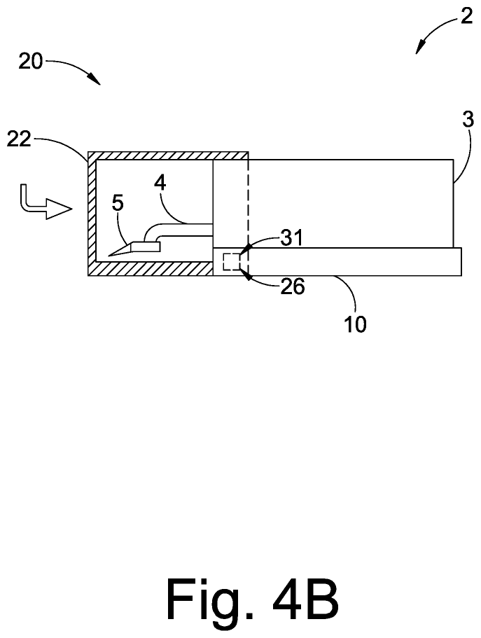

Please refer to FIG. 3 again and to FIG. 4A and FIG. 4B. FIG. 4A shows a schematic diagram of the structure according to the second embodiment of the present invention; FIG. 4B shows a cross-sectional view of the structure according to the second embodiment of the present invention. As shown in the figures, according to the present embodiment, the base 10 is disposed below the signal processing module 3 for supporting. An alignment part 31 is disposed on one side of the base 10. The shielding member 20 includes a shielding body 22, a side opening 24, and a fixing part 26. The side opening 24 passes through one side of the shielding body 22, covers the signal processing module 3 correspondingly, and envelops the conducting member 4 and the probe 5. The fixing part 26 of the shielding member 20 is disposed at the shielding body 22 corresponding to the fixing part 31. According to the present embodiment, the material of the base 10 is, but not limited to, metal. The detection device 2 according to the present embodiment is identical to the one according to the first embodiment. Hence, the details will not be repeated.

According to the present embodiment, the alignment part 31 is disposed on one side of the base 10 corresponding to the fixing part 26 of the shielding body 22 for fixing the shielding member 20 on the outer side of the base 10. Thereby, according to the present embodiment, the size (for example, the width of the opening) of the side opening 24 of the shielding body 22 must be greater than the size of the signal processing module 3 and the base 10 for covering the signal processing module 3 and the base 10 and preventing the signal processing module 3 and the base 10 from damage.

Please refer to FIG. 3 to FIG. 4B again. As shown in the figures, according to the present embodiment, the detachable protective structure of detection device 1 further comprises a fixing member F. The fixing member F passes through the fixing part 26 at the shielding body 22 and the alignment part 31 at the signal processing module 3 for fixing the shielding member 20 to the outer side of the signal processing module 3. According to the present embodiment, the fixing part 26 and the alignment part 31 are screw holes, respectively. The fixing member F is a threaded member. The threaded member is screwed into the screw holes for fixing. Nonetheless, the present invention is not limited to the embodiment.

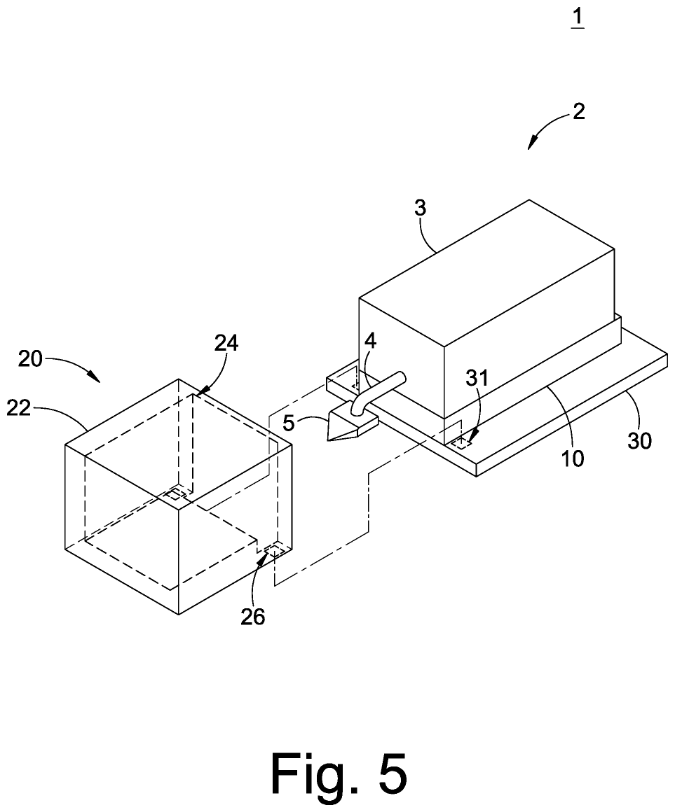

Please refer to FIG. 5, which shows an exploded view of the structure according to the third embodiment of the present invention. As shown in the figure, the third embodiment of the present invention discloses a detachable protective structure of detection device 1, which is used for accommodating a detection device 2. The detection device 2 includes a signal processing module 3, a conducting member 4, and a probe 5. One terminal of the conducting member 4 is connected electrically to the signal processing module 3. The other terminal of the conducting member 4 is connected electrically to the probe 5. The detachable protective structure of detection device 1 comprises a base 10, a platform 30, and a shielding member 20. According to the present embodiment, the probe 5 is a waveguide probe. According to the present embodiment, the signal processing module 3 is a frequency extension module or a load adjustment module of the waveguide probe. The present invention is not limited to the present embodiment.

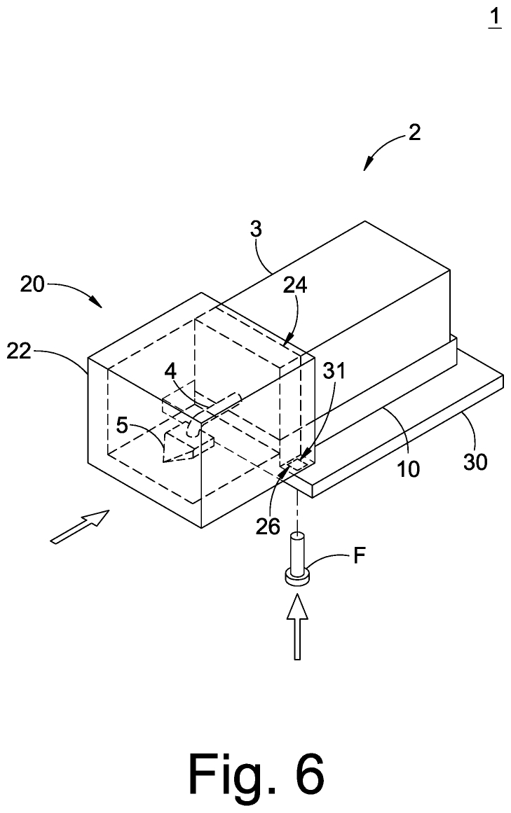

Please refer to FIG. 5 again and to FIG. 6, which shows a schematic diagram of the structure according to the third embodiment of the present invention. As shown in the figures, according to the present embodiment, the base 10 is disposed below the signal processing module 3 for supporting. The platform 30 is disposed below the base 10. The platform 30 is a movable device that can move the detection device 2 and the base 10 correspondingly. An alignment part 31 is disposed on the platform 30. The shielding member 20 includes a shielding body 22, a side opening 24, and a fixing part 26. The side opening 24 passes through one side of the shielding body 22, covers the signal processing module 3 correspondingly, and envelops the conducting member 4 and the probe 5. The fixing part 26 of the shielding member 20 is disposed below the shielding body 22 corresponding to the fixing part 31. According to the present embodiment, the material of the base 10 and the platform 30 is, but not limited to, metal. The detection device 2 according to the present embodiment is identical to the one according to the first embodiment. Hence, the details will not be repeated.

According to the present embodiment, the alignment part 31 is disposed on the platform 30 corresponding to the fixing part 26 of the shielding body 22 for fixing the shielding member 20 on the platform 30. Thereby, according to the present embodiment, the size (for example, the width of the opening) of the side opening 24 of the shielding body 22 must be greater than the size of the signal processing module 3 and the base 10 and smaller than the size of the platform 30 for covering the signal processing module 3 and the base 10, disposing the shielding body 22 on the platform 30 correspondingly, and preventing the signal processing module 3 and the base 10 from damage.

Please refer to FIG. 5 to FIG. 6 again. As shown in the figures, according to the present embodiment, the detachable protective structure of detection device further comprises a fixing member F. The fixing member F passes through the fixing part 26 at the shielding body 22 and the alignment part 31 at the platform 30 for fixing the shielding member 20 on the platform 30 and for preventing deterioration of detection quality owing to movement of the detachable protective structure of detection device 1. According to the present embodiment, the fixing part 26 and the alignment part 31 are screw holes, respectively. The fixing member F is a threaded member. The threaded member is screwed into the screw holes for fixing. Nonetheless, the present invention is not limited to the embodiment.

According to the present embodiment, the fixing member F passes through the platform 30 and the shielding body 22 top down for fixing the shielding member 20 on the platform 30 and for preventing deterioration of detection quality owing to movement of the detachable protective structure of detection device 1.

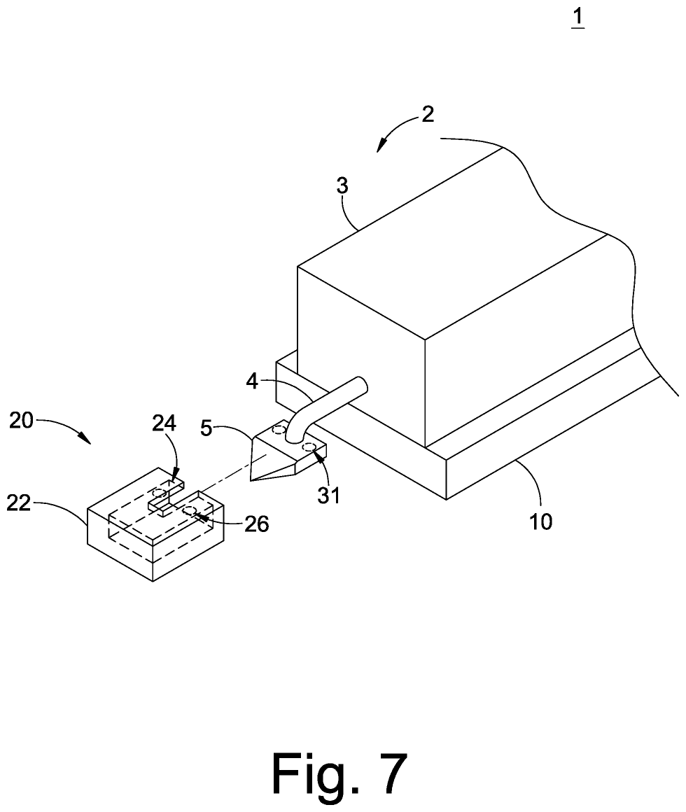

Please refer to FIG. 7, which shows an exploded view of the structure according to the fourth embodiment of the present invention. As shown in the figure, the fourth embodiment of the present invention discloses a detachable protective structure of detection device 1, which is used for accommodating a detection device 2. The detection device 2 includes a signal processing module 3, a conducting member 4, and a probe 5. One terminal of the conducting member 4 is connected electrically to the signal processing module 3. The other terminal of the conducting member 4 is connected electrically to the probe 5. The detachable protective structure of detection device 1 comprises a shielding member 20. According to the present embodiment, the probe 5 is a waveguide probe. According to the present embodiment, the signal processing module 3 is a frequency extension module or a load adjustment module of the waveguide probe. The present invention is not limited to the present embodiment.

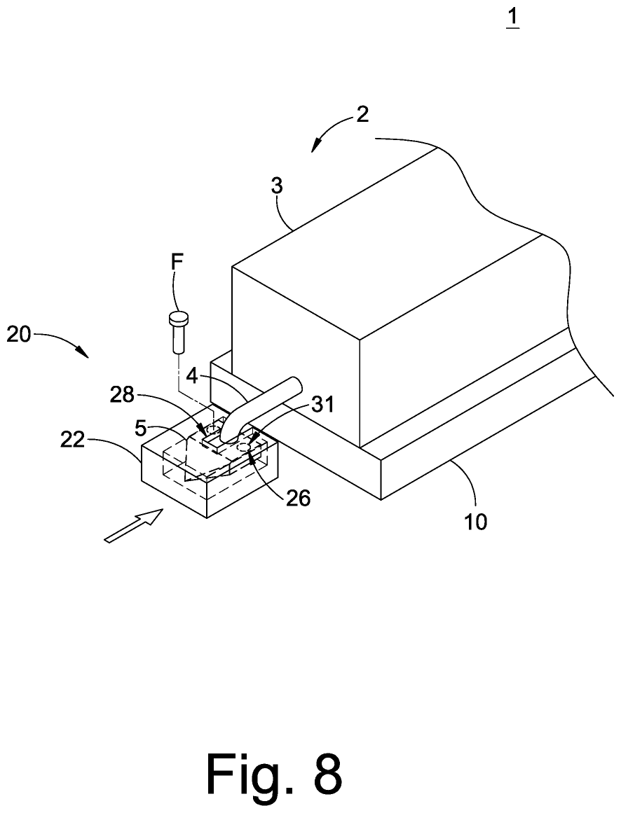

Please refer to FIG. 7 and FIG. 8. FIG. 8 shows a schematic diagram of the structure according to the fourth embodiment of the present invention. As shown in the figures, according to the present embodiment, the shielding member 20 includes a shielding body 22, a side opening 24, a top opening 28, and a fixing part 26. The side opening 24 passes through one side of the shielding body 22, covers the signal processing module 3 correspondingly, and envelops the conducting member 4 and the probe 5. The top opening 28 is connected to the side opening 24 and forming an L-shaped opening. The conducting member 4 passes through the top opening 28. The fixing part 26 of the shielding member 20 is disposed at the shielding body 22 corresponding to an alignment part 31 of the probe 5 for fixing the shielding member 20 to the probe 5. The detection device 2 according to the present embodiment is identical to the one according to the first embodiment. Hence, the details will not be repeated.

According to the present embodiment, the alignment part 31 is disposed on the probe 5 corresponding to the fixing part 26 of the shielding body 22 for fixing the shielding member 20 on the probe 5. Thereby, according to the present embodiment, the size (for example, the width of the opening) of the side opening 24 of the shielding body 22 must be greater than the size of the probe 5 for covering the probe 5. The size of the top opening 28 must be greater than the size of the conducting member 4 for allowing the conducting member 4 to pass through and preventing the probe 5 and the conducting member 4 from damage.

Please refer to FIG. 7 to FIG. 8 again. As shown in the figures, according to the present embodiment, the detachable protective structure of detection device further comprises a fixing member F. The fixing member F passes through the fixing part 26 at the shielding body 22 and the alignment part 31 at the probe 5 for fixing the shielding member 20 to the probe 5. According to the present embodiment, the fixing part 26 and the alignment part 31 are screw holes, respectively. The fixing member F is a threaded member. The threaded member is screwed into the screw holes for fixing. Nonetheless, the present invention is not limited to the embodiment.

The present invention provides a shielding and protective structure for the detection device 2. By covering the conducting member 4 and/or the probe 5 using the shielding member 20, the devices can be protected and avoiding pollutants such as dust, hair from polluting the probe 5. To install the detection device 2 on the detection platform, the present embodiment can be assembled to the platform together with the detection device 2. Likewise, they can be disassembled together. To use the detection device 2, the shielding member 20 is opened to expose the probe 5. After usage, the shielding member 20 covers and protects the probe 5. In addition, after usage, the shielding member 20 and the base 10 can be disassembled altogether from the platform 30 for reducing movement of the detection device 2.

To sum up, the present invention provides a detachable protective structure of detection device. A signal processing module loaded with a probe can be disposed directly on the structure according to the present invention for protecting the probe and the signal processing module from external impact and pollution. In addition, while changing machines, the detection device can omit the step of disassembling the probe (for example, the RF probing device) from the signal processing module. Instead, the probe and the signal processing module can be disassembled together for protecting the probe from external impact, reducing disassembling time, and lowering risks of bump at devices. According to the prior art, the detection device needs to be accommodated in an accommodating box. The disassembling and storing process is quite complicated and time-consuming. The storing process will increase the possibility of bump between the signal processing module and the probe as well as the possibility of human contact. Both possibilities will lead to damage risks.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A detachable protective structure of detection device for accommodating a detection device, said detection device including a signal processing module, a conducting member, and a probe, said conducting member disposed on one side of said signal processing module with one terminal connected electrically to said signal processing module, the other terminal of said conducting member connected electrically to one side of said probe, and said detachable protective structure of detection device comprising:
a shielding member, including a shielding body, a side opening, and a fixing part, said side opening passing through one side of said shielding body, covering said signal processing module correspondingly, and enveloping said conducting member and said probe, and said fixing part disposed at said shielding body corresponding to an alignment part of said signal processing module.

2. The detachable protective structure of detection device of claim 1, further comprising a fixing member, passing through said fixing part and said alignment part correspondingly.

3. The detachable protective structure of detection device of claim 2, wherein said fixing part and said alignment part are screw holes, respectively, and said fixing member is a threaded member.

4. The detachable protective structure of detection device of claim 1, further comprising a base, disposed below said signal processing module.

5. A detachable protective structure of detection device for accommodating a detection device, including a signal processing module, a conducting member, and a probe, said conducting member disposed on one side of said signal processing module with one terminal connected electrically to said signal processing module, the other terminal of said conducting member connected electrically to one side of said probe, and said detachable protective structure of detection device comprising:
a base, disposed below said signal processing module, and an alignment part disposed on one side of said base; and
a shielding member, including a shielding body, a side opening, and a fixing part, said side opening passing through one side of said shielding body, covering said signal processing module correspondingly, and enveloping said conducting member and said probe, and said fixing part disposed at said shielding body corresponding to said alignment part of said signal processing module.

6. The detachable protective structure of detection device of claim 5, further comprising a fixing member, passing through said fixing part and said alignment part correspondingly.

7. The detachable protective structure of detection device of claim 6, wherein said fixing part and said alignment part are screw holes, respectively, and said fixing member is a threaded member.

8. A detachable protective structure of detection device for accommodating a detection device, including a signal processing module, a conducting member, and a probe, said conducting member disposed on one side of said signal processing module with one terminal connected electrically to said signal processing module, the other terminal of said conducting member connected electrically to one side of said probe, and said detachable protective structure of detection device comprising:
a base, disposed below said signal processing module;
a platform, disposed below said base and including an alignment part; and
a shielding member, including a shielding body, a side opening, and a fixing part, said side opening passing through one side of said shielding body, covering said signal processing module correspondingly, and enveloping said conducting member and said probe, and said fixing part disposed below said shielding body corresponding to said alignment part.

9. The detachable protective structure of detection device of claim 8, further comprising a fixing member, passing through said fixing part and said alignment part correspondingly.

10. The detachable protective structure of detection device of claim 9, wherein said fixing part and said alignment part are screw holes, respectively, and said fixing member is a threaded member.

11. A detachable protective structure of detection device for accommodating a detection device, including a signal processing module, a conducting member, and a probe, said conducting member disposed on one side of said signal processing module with one terminal connected electrically to said signal processing module, the other terminal of said conducting member connected electrically to one side of said probe, and said detachable protective structure of detection device comprising:
a shielding member, including a shielding body, a side opening, a top opening, and a fixing part, said side opening passing through one side of said shielding body, and covering and enveloping said probe, said top opening connected with said side opening, said conducting member passing through said top opening, and said fixing part disposed at said shielding body corresponding to an alignment part on said probe.

12. The detachable protective structure of detection device of claim 11, further comprising a fixing member, passing through said fixing part and said alignment part correspondingly.

13. The detachable protective structure of detection device of claim 12, wherein said fixing part and said alignment part are screw holes, respectively, and said fixing member is a threaded member.

14. The detachable protective structure of detection device of claim 11, further comprising a base, disposed below said signal processing module.
